(19) United States
(12) Patent Application Publication
(10) Pub. No.: US 2022/0085107 A1
(43) Pub. Date: Mar. 17, 2022

(54) TOPOLOGIES OF UNIT CROSSBARS

(71) Applicant: Knowm, Inc., Santa Fe, NM (US)

(72) Inventor: Alex Nugent, Santa Fe, NM (US)

(21) Appl. No.: 17/459,389

(22) Filed: Aug. 27, 2021

Related U.S. Application Data
(60) Provisional application No. 63/072,184, filed on Aug. 30, 2020.

(51) Int. Cl. H01L 27/24

(52) U.S. Cl. CPC H01L 27/2463

(57) ABSTRACT

A memristor apparatus can include one or more crossbar arrays and a memory bit M cell. Furthermore, a group of select bits can be shared, wherein an enable signal for each unit crossbar among the crossbars in the one or more crossbar arrays can be generated by the memory bit M cell. In an embodiment of the memristor apparatus, each unit crossbar can share select control lines and may use row/column enable lines.

### CROSS-REFERENCE TO PROVISIONAL APPLICATION

This patent application claims priority under 35 U.S.C. § 119(e) to U.S. Provisional Patent Application Ser. No. 63/072,184 entitled “Topologies of Unit Crossbars,” which was filed on Aug. 30, 2020, the disclosure of which is incorporated herein by reference in its entirety.

### TECHNICAL FIELD

Embodiments relate to electronic architectures for computing systems. Embodiments also relate to memristors. Embodiments further relate to memristor computing architectures including crossbars.

### BACKGROUND

As Moore's law ends, future computing system gains will come through changes in integrated electronic architecture, enabling nanotechnology and photonics integration. Memristors, for example, may offer a significant and enabling feature set that can transform memory, logic and artificial intelligence.

While modern transistor sizes are now smaller than many viruses and biological synapses, the great power discrepancy between modern methods of computing and biological brains indicate that upwards of six to nine orders of magnitudes of gains may be realized through integrations of memristors and CMOS arrangements in new computing architectures.

Memristors have been defined as devices that include two-terminal variable resistance changing elements. While much has been written about memristors regarding the theoretical definition, for our disclosure we use the word ‘memristor’ to indicate a two-terminal resistance changing element such that the application of voltage bias exceeding some threshold will increase the conductance of the element and a reverse voltage bias exceeding some threshold will decrease the conductance of the element.

Memristor crossbars have been heavily investigated for their use in memristor computing systems due to the high density of memristor elements obtainable. Memristive material located at the intersection of addressable rows and columns can be accessed by electrically driving selected rows and columns. Provided the memristors have a forward and reverse threshold above the thermal noise level, it may be possible to write and erase elements of a crossbar without disturbing other elements. This is because the voltage drop applied across the selected device will see the largest voltage drop, while un-selected devices will see a reduced voltage drop. If the reduced voltage drop is less than the threshold while the full voltage drop is above device threshold, selective programing can occur. However, there are still limitations to crossbars that limit how they can be used and how large they can grow before problem arise.

One limitation of crossbars is caused by the “sneak-path” problem. In this case, if it is desired to access only part of a crossbar, i.e. to apply voltage to only one or a few columns/rows and to leave others electrically floating, then currents can pass from one column or row to another through a floating row or column. One solution to the sneak-path problem is to include “selector devices” in series with each memristors. The most common and reliable solution is to use a single access transistor in series with the memristor, called a “1T1R” configuration. Selector transistors are not ideal as they consumes all of the active portion of an integrated chip under the memristor array before row/column access circuitry such as row and column decoders are even considered. Another problem with crossbars, in terms of using them to directly represent a matrix-multiply operation in a neural network is that the topology is fixed. That is, by a crossbars very nature every column is connected to every row.

While this topology can match a fully connected neural network layer, it unfortunately presents a significant problem. The sneak-path problem limits only relatively small crossbars from being used, while much larger matrix multiplies are needed in practice. For example, a typical neuromorphic “neuron” may contain upwards thousands of inputs, while a crossbar larger than about 64 rows or columns will experience degrading performance due to sneak paths. It is simply not possible to construct memristor crossbars with thousands of rows and/or columns without the use of selector devices. Furthermore, if even one junction of the matrix contains a “stuck-on” fault (for example, due to a memristor stuck in its low resistance state), this may cripple the whole crossbar.

### BRIEF SUMMARY

The following summary is provided to facilitate an understanding of some of the innovative features unique to the disclosed embodiments and is not intended to be a full description. A full appreciation of the various aspects of the embodiments disclosed herein can be gained by taking the entire specification, claims, drawings, and abstract as a whole.

It is, therefore, one aspect of the embodiments to provide for a memristor crossbar for use in memristor computing systems.

It is another aspect of the embodiments to provide for an improved crossbar array and crossbar unit.

It is also an aspect of the embodiments to provide a meta array for use with crossbar arrays and crossbar units in memristor crossbars and memristor computing systems.

If is a further aspect of the embodiments to provide for a differential-pair meta array for use with crossbar arrays and crossbar units in memristor crossbars and memristor computing systems.

The aforementioned aspects and other objectives and advantages can now be achieved as described herein. In an embodiment, a memristor apparatus can include at least one crossbar array and a memory bit M cell; a plurality of select bits that are shared; and wherein an enable signal for each unit crossbar in the at least one crossbar array can be generated by the memory bit M cell.

In an embodiment of the memristor apparatus, the each unit crossbar can share select control lines and uses row/column enable lines.

In an embodiment of the memristor apparatus, the at least one crossbar array can comprise a meta array.

In an embodiment of the memristor apparatus, the at least one crossbar array can comprise a differential-pair meta array.

In an embodiment of the memristor apparatus, the at least one crossbar array can comprise a plurality of differential pairs of unit crossbars.

In an embodiment, a meta array, can comprise at least one crossbar array; a memory bit M cell; a plurality of select bits that are shared; and an enable signal for each unit crossbar among the at least one crossbar generated by the memory bit M cell.

In an embodiment, the each unit crossbar can share select control lines and use row/column enable lines.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the embodiments.

FIG. 1 illustrates an example of a symbolic representation of a memristor 10, which can be utilized in accordance with the embodiments.

FIG. 2 depicts a schematic diagram of a memristor crossbar array having analog multiplexers that can function as row and column decoders;

FIG. 3A and FIG. 3B illustrate a schematic diagram of a unit crossbar, in accordance with an embodiment;

FIG. 4A and FIG. 4B illustrate a schematic diagram depicting column or row decoder and access circuitry, in accordance with an embodiment;

FIG. 5 illustrates a schematic diagram of a crossbar that can be formed of unit crossbars, in accordance with an embodiment;

FIG. 6 illustrates a schematic diagram of a crossbar in which elements can be isolated from the active row and columns, in accordance with an embodiment;

FIG. 7 illustrates a schematic diagram of a meta array wherein select bits can be shared and the enable signal for each unit crossbar can be generated by a memory bit M cell, in accordance with an embodiment;

FIG. 8A and 8B illustrates a schematic diagram of a non-topological meta array with circuit representation (A) and symbolic representation (B), in accordance with an embodiment; and

FIG. 9A and 9B illustrates a schematic diagram of a differential-pair meta array, in accordance with an embodiment.

### DETAILED DESCRIPTION

The particular values and configurations discussed in these non-limiting examples can be varied and are cited merely to illustrate one or more embodiments and are not intended to limit the scope thereof. Exemplary embodiments are intended to cover all alternatives, modifications, and equivalents as may be included within the spirit and scope of the composition, apparatus and systems as described herein.

A more complete understanding of the processes, systems and apparatuses disclosed herein can be obtained by reference to the accompanying drawings. These figures are merely schematic representations based on convenience and the ease of demonstrating the existing art and/or the present development, and are, therefore, not intended to indicate relative size and dimensions of the assemblies or components thereof. In the drawing, like reference numerals may be used throughout to designate similar or identical elements.

Subject matter will now be described more fully hereinafter with reference to the accompanying drawings, which form a part hereof, and which show, by way of illustration, specific example embodiments. Subject matter may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware, or any combination thereof (other than software per se). The following detailed description is, therefore, not intended to be interpreted in a limiting sense.

Throughout the specification and claims, terms may have nuanced meanings suggested or implied in context beyond an explicitly stated meaning. Likewise, phrases such as “in one embodiment” or “in an example embodiment” and variations thereof as utilized herein do not necessarily refer to the same embodiment and the phrase “in another embodiment” or “in another example embodiment” and variations thereof as utilized herein may or may not necessarily refer to a different embodiment. It is intended, for example, that claimed subject matter include combinations of example embodiments in whole or in part.

In general, terminology may be understood, at least in part, from usage in context. For example, terms such as “and,” “or,” or “and/or” as used herein may include a variety of meanings that may depend, at least in part, upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein, depending at least in part upon context, may be used to describe any feature, structure, or characteristic in a singular sense or may be used to describe combinations of features, structures, or characteristics in a plural sense. Similarly, terms such as “a,” “an,” or “the”, again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to components of like function.

The modifier “about” used in connection with a quantity may be inclusive of the stated value and can have a meaning dictated by the context (for example, it may include at least the degree of error associated with the measurement of the particular quantity). When used with a specific value, it should also be considered as disclosing that value. For example, the term “about 2” also discloses the value “2” and the range “from about 2 to about 4” also discloses the range “from 2 to 4.”

Although embodiments are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. For example, “a plurality of stations” may include two or more stations. The terms “first,” “second,” and the like, herein do not denote any order, quantity, or importance, but rather can be used to distinguish one element from another. The terms “a” and “an” herein may not denote a limitation of quantity, but rather can denote the presence of at least one of the referenced item.

As utilized herein, the term ‘memristor’ can relate to a two-terminal resistance changing element, wherein the application of a voltage bias exceeding some threshold can increase the conductance of the element and a reverse voltage bias exceeding some threshold can decrease the conductance of the element. The term ‘memristor’ can also refer to a non-linear two-terminal electrical component relating electric charge and magnetic flux linkage. In addition, the term ‘memristor’ can relate to the memristor device (and improvements thereof) described and named in 1971 by Leon Chua, completing a theoretical quartet of fundamental electrical components, which also include the resistor, capacitor and inductor.

The disclosed embodiments relate to memristors and memristor computing architectures based on crossbars in novel configurations that overcome the limitations of previous approaches discussed in the background section of this disclosure. The disclosed embodiments also relate to methods, processes, and techniques of building memristor computing architectures from crossbars in novel configurations that overcome the limitations of the previous approaches.

The disclosed embodiments provide a solution to the problem of scaling crossbars by providing alternative architectures formed from arrays of smaller crossbars, for example 64×64, 32×32, or even smaller. Provided a memristor can be fabricated with forward and reverse thresholds, a small memristor crossbar may be perfectly functional.

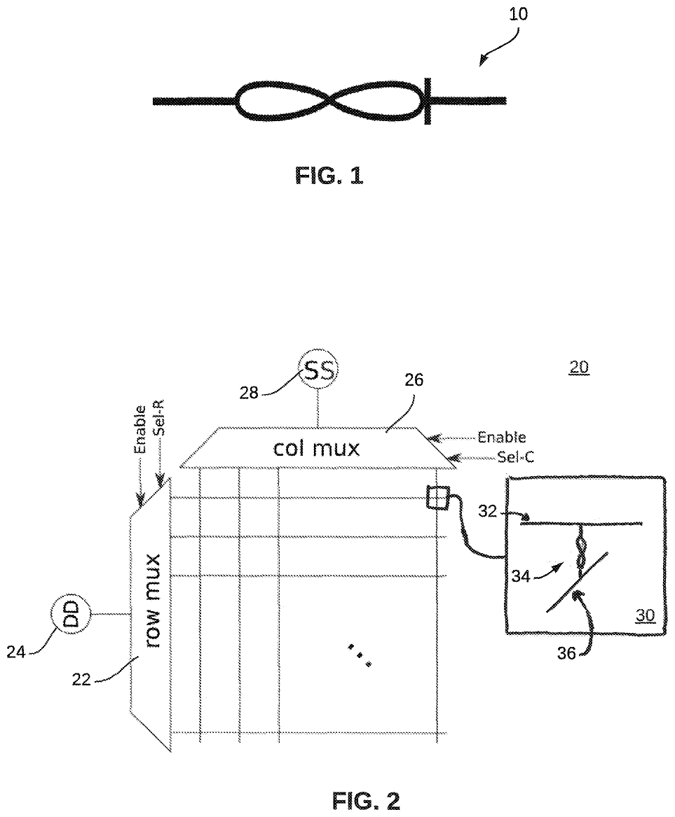

FIG. 1 illustrates an example of a symbolic representation of a memristor 10, which can be utilized in accordance with the embodiments. This symbol has been used internally at Knowm, Inc. (the Assignee of this patent application) as it is easier to draw by hand and can more accurately represent a defining characteristic of a memristor. As Leon Chua, the theoretical inventor of the memristor, has said: “If it's pinched it's a memristor”. A voltage can applied across the device (forward voltage) with the lower-potential end on the side of the bar, will drive the device into a high conductance state, while a reverse voltage will drive the device into a less conductive state. By convention, a bar can signify the lower potential end in other devices like diodes.

FIG. 2 depicts a schematic diagram of a memristor crossbar array 20 having analog multiplexers that can function as row and column decoders. FIG. 2 is presented herein to explain problems with current memristor solutions. As shown in FIG. 2, the memristor crossbar array 20 can include a row multiplexer 22 (also depicted in FIG. 2 as ‘row mux’) and a column multiplexer 26 (also shown in FIG. 2 as ‘col mux’). A DD (drain) line 24 can engage with the row multiplexer 2, and a SS (source) line 28 can enage with the column multiplexer 26.

A graphical representation of a node 30 is shown at the right hand side of FIG. 2. The example node 30 can include a top electrode (column) 32, which can connect to a memristor 34 that in turn can be connected to a bottom electrode (row) 36. Enable and Sel-C lines can connect to the column multiplexer 26. Similarly, enable and Sel-R lines can connect to the row multiplexer 22, as depicted in FIG. 2.

As discussed previously, one limitation of crossbars such as shown in FIG. 2 may be caused by the “sneak-path” problem. In the case of the configuration shown in FIG. 2, if it is desired to access only part of a crossbar, i.e. to apply voltage to only one or a few columns/rows and to leave others electrically floating, then currents can pass from one column or row to another through a floating row or column. One solution to the sneak-path problem may be to include “selector devices” in series with each memristors. The most common method is to use a single access transistor in series with the memristor, called a “1T1R” configuration. Selector transistors may not be ideal as they consume all of the active portion of an integrated chip under the memristor array before row/column access circuitry such as row and column decoders are even considered.

Another problem with crossbars as shown in the example illustration of FIG. 2, in terms of using them to directly represent a matrix-multiply operation in a neural network is that the topology may be fixed. That is, by crossbars' very nature every column may be connected to every row. While this topology may match a fully connected neural network layer, unfortunately there is a significant problem. The sneak-path problem limits only relatively small crossbars from being used, while much larger matrix multiplies are needed in practice. For example, a typical neuromorphic “neuron” may contain upwards thousands of inputs, while a crossbar larger than about 64 rows or columns will experience degrading performance due to sneak paths. It is simply not possible to construct memristor crossbars with thousands of rows and/or columns without the use of selector devices. Furthermore, if even one junction of the matrix contains a “stuck-on” fault, for example, due to a memristor stuck in its low resistance state it may cripple the whole crossbar.

A solution to the problem of scaling crossbars can involve exploring alternative architectures formed from arrays of smaller crossbars, for example 64×64, 32×32, or even smaller. Provided a memristor can be fabricated with forward and reverse thresholds, a small memristor crossbar may be perfectly functional.

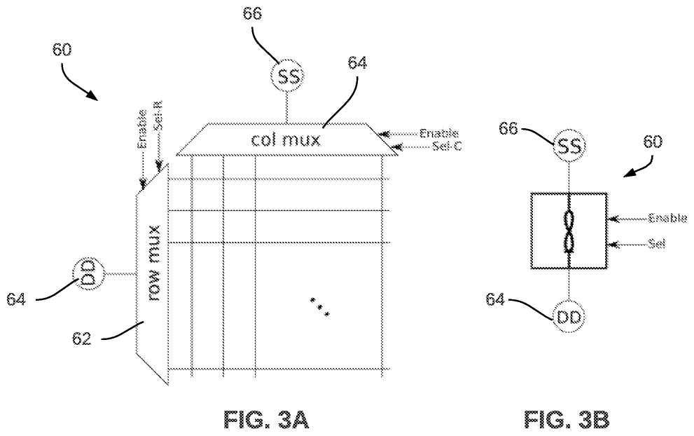

Consider a small “unit crossbar” formed of row and column bi-directional (pass-though) analog multiplexers and a small crossbar, as depicted in FIG. 3A and FIG. 3B. That is, FIG. 3A and FIG. 3B illustrate a schematic diagram of a unit crossbar 60, in accordance with an embodiment.

The unit crossbar 60 shown in FIG. 3A and FIG. 3B can allow access of one device on the crossbar at a time though selection of the row and column via control lines Sel-R (row select) and Sel-C (column select). Furthermore, the unit crossbar 60 can be disabled with the enable line such that when the unit crossbar 60 is disabled, there are no conductive paths and the memristor crossbar is electrically isolated from SS (source) and DD (drain) lines. Note that FIG. 3B depicts a symbolic representation of the unit crossbar 60 shown in FIG. 3A. The unit crossbar 60 as depicted in FIG. 3A can include a column multiplexer 64 that can connect to an SS line 66 and also can be subject to an enable line and a Sel-C line. The unit crossbar 60 further can include a row multiplexer 62 that can connect to a DD (drain) line 64.

When the crossbar unit is active, one column and one row can be selected, causing the electrical coupling of the selected memristor (e.g., see the memristor symbol shown in FIG. 3B) with the SS (source) line 66 and the DD (drain) line 64. We can view this unit crossbar as a single memristor element in a larger architecture, where the at any given time 1 out of N memristors can be enabled, or else no memristors are enabled and the circuit is open. We represent the unit crossbar as a box around a memristor symbol with SS, DD, Enable and Select lines, as shown in FIG. 3B. Of note is the Sel (select) line is actually a bus composed of log 2(Nr)+log 2(Nc) lines, where Nr is the number of rows, Nc is the number of columns, and log 2( )is the base 2 logarithm.

While the unit crossbar of the embodiments can necessarily contain row and column access circuitry, it may not contain selector devices. A crossbar with selector devices, whether or not they are formed of transistors, diodes, etc, may still require row and column access circuitry. Because the number of memristors scales as the product of the number of rows and columns while the transistor count for a row or column access scales linearly, the effective number of transistors per memristor is reduced as the crossbar grows. While we are still limited to small crossbars, the effect is still substantial.

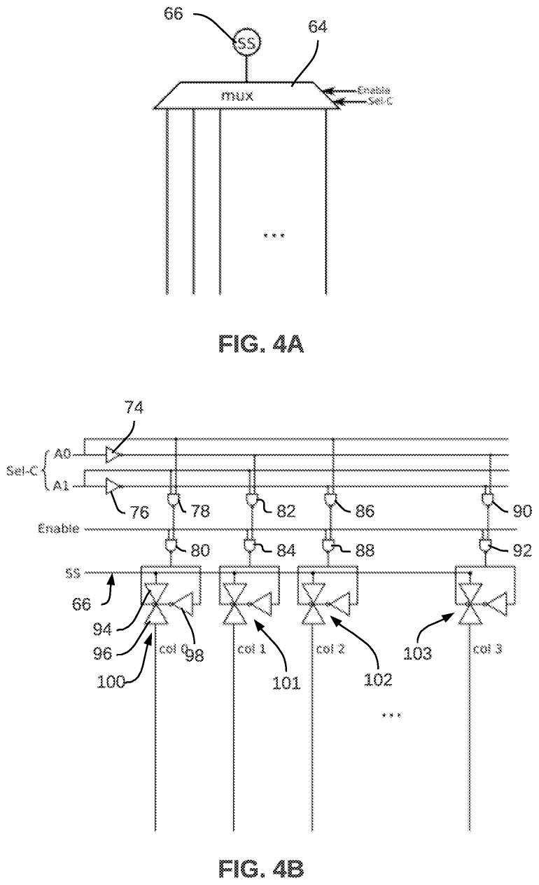

FIG. 4A and FIG. 4B illustrate a schematic diagram depicting column or row decoder and access circuitry, in accordance with an embodiment. An example column or row access circuit is shown in FIG. 4A and FIG. 4B, where row/column select bits (A0, A1) are converted to a “1 of N” encoding via NAND gates. While we show four two-input NAND gates and two select bits, it can be appreciated that more rows require more select bits and consequently NAND gates with more inputs. A SS (source) 66 line is shown in the example of FIG. 4A with respect to a multiplexer 64, which in turn may be subject to enable and Sel-C lines.

Details of the configuration shown in FIG. 4A are depicted in FIG. 4B. For example, as shown in FIG. 4B, an inverter 74 may connect to an AO line and an inverter 76 may connect to an A1 line. The A1 and AO lines may comprise the Sel-C lines (i.e., same Sel-C lines shown in FIG. 4A). Examples of the NAND gates discussed above are shown in FIG. 4B as, for example, NAND gates 78, 82, 86 and NAND gates 80, 84, 88. Additional components can include an SS line 66 and a pass or transmission gate formed of components 94, 96 as well as the inverter 98.

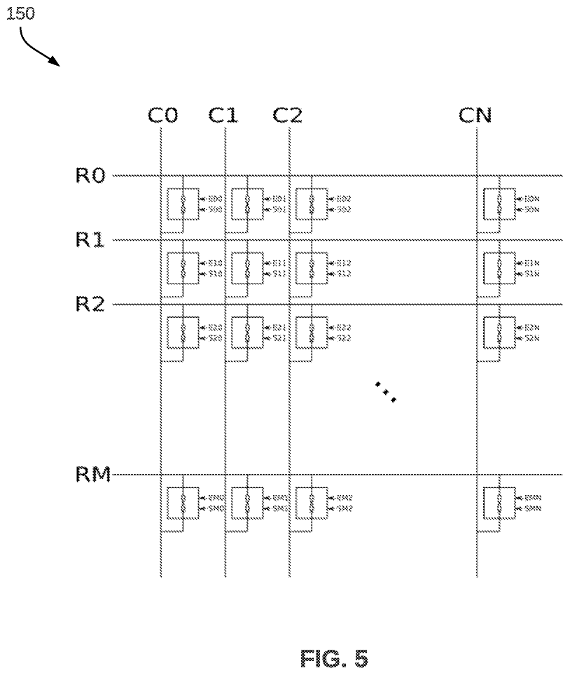

Because a crossbar unit may act as a selector device, large crossbar arrays formed of unit crossbars can be used to perform desired computations without the issue of sneak-path currents. This can be seen in the crossbar unit 150 shown in FIG. 5, where we can employ unit crossbars at each intersection of rows and columns. FIG. 5 thus illustrates a schematic diagram of a crossbar 150 formed of unit crossbars, in accordance with an embodiment. Note that the term ‘crossbar unit’ and ‘unit crossbar’ and ‘crossbar’ can be utilized herein interchangeably to refer to the same device.

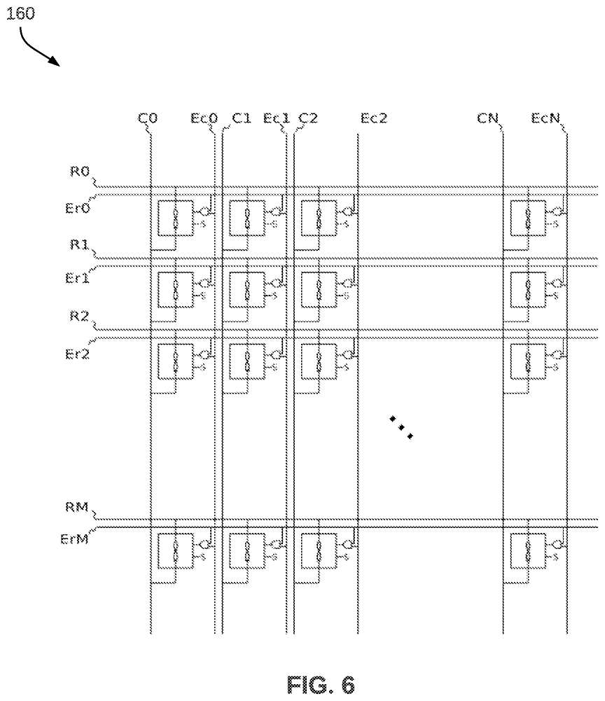

While each unit crossbar can be controlled with unique enable and select control lines (E00, E01, . . . E0N etc), doing so would be costly from a circuit resources perspective. Instead, unit crossbars can share select control lines and use row/column enable lines, as shown in FIG. 6. FIG. 6 illustrates a schematic diagram of a crossbar 160 in which elements can be isolated from the active row and columns, in accordance with an embodiment. As will be discussed below, the crossbar unit 160 may comprise or function as a meta array.

This can be seen in FIG. 6, where we use the same selection bits to select the same relative row/column from each crossbar unit, and row and column enable lines (Ec0/Er0, Ec1/Er1, etc) combined with a NAND gate for the unit crossbar enable. In this manner we have created a more ideal crossbar where elements can be isolated from the active row and columns in a similar manner to a selector device. However, because each memristor element of the crossbar is formed from a unit crossbar, we have actually created N distinct larger crossbars which are selectable by the select bit lines (S). As an example, we may form a larger array, for example 1024×64, from 32×32 unit crossbars. Such a design would consume approximately 55 million transistors, 67 million memristors and provide access to 1024 distinct 1024×64 memristor crossbars without sneak-path issues. We will call this larger array of crossbar unit arrays a “meta array”.

While it may at first appear that using unit crossbars is overly costly, it is in fact an ideal strategy when considered in the context of larger accelerators, for example a deep neural network with dozens or even hundreds of layers. In this context, a single meta array could handle the whole network, or even multiple networks for multiple applications, each electrically isolated from each other and selectable via the selection bits (S).

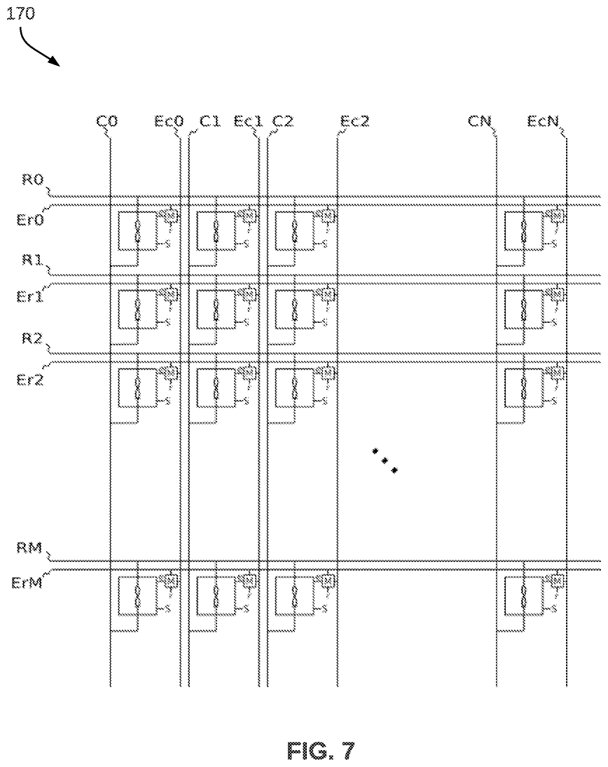

One potential problem with the meta array of the crossbar unit shown in FIG. 6 is that the row and column enable circuitry may limit which unit crossbars can be enabled at the same time. This can be fixed by using a memory bit element, M, as the enable signal for each unit crossbar, as shown in the meta array 170 of FIG. 7. FIG. 7 illustrates a schematic diagram of a meta array 170, wherein select bits can be shared and the enable signal for each unit crossbar can be generated by a memory bit M cell, in accordance with an embodiment.

If each unit crossbar enable signal is generated by a memory bit cell, which in turn is set with row and column enable lines and shared reset signal ‘r’, then any unit crossbar can be co-enabled with any other unit crossbar in the meta array. This is a much more ideal scenario for sparse matrix connectivity. Memory cell “M” could be, for example, an SRAM cell, a DRAM cell, a memristor or resistive-ram cell or other technology. To use the meta array, the reset signal would first clear all the memory units, causing all unit crossbars to be decoupled (disabled). Next, the row and column enable lines would be used to enable select memory cells in the meta array.

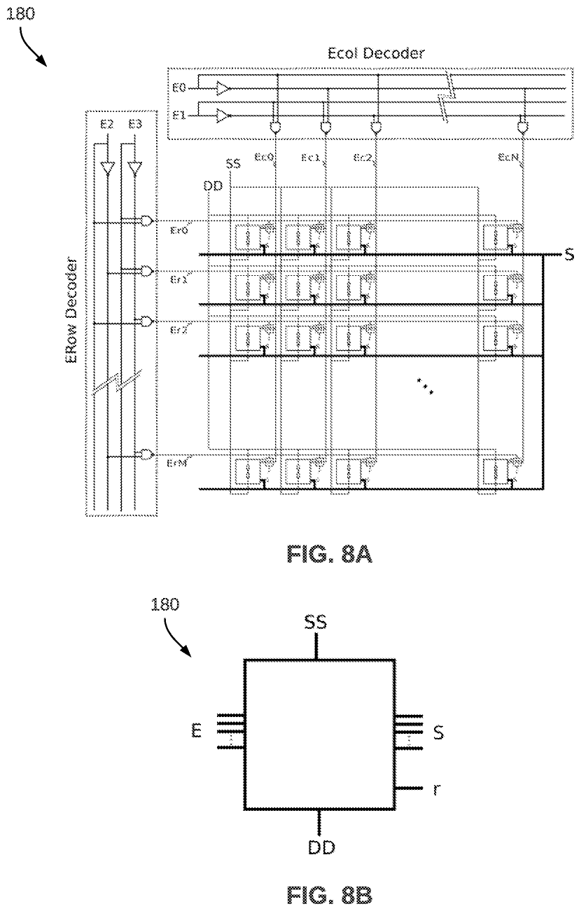

FIG. 8A and 8B illustrates a schematic diagram of a non-topological meta array 180 with circuit representation and symbolic representation, in accordance with an embodiment. That is, a circuit diagram or circuit representation of the meta array 180 is shown in FIG. 8A, and a symbolic representation of the same meta array 180 is depicted in FIG. 8B.

While individual row/column drivers may be used, a large non-topological array can be formed by joining the column to form one input (SS) and joining the rows to form one output (DD). When paired with a memory cell access as depicted FIG. 7, such a design can provide access to “N” linear arrays, where N is the number of elements in the constituent unit crossbars. Such a design is useful if very large numbers of potential co-active memristors are desired, for example emulating a neuron with many thousands of inputs.

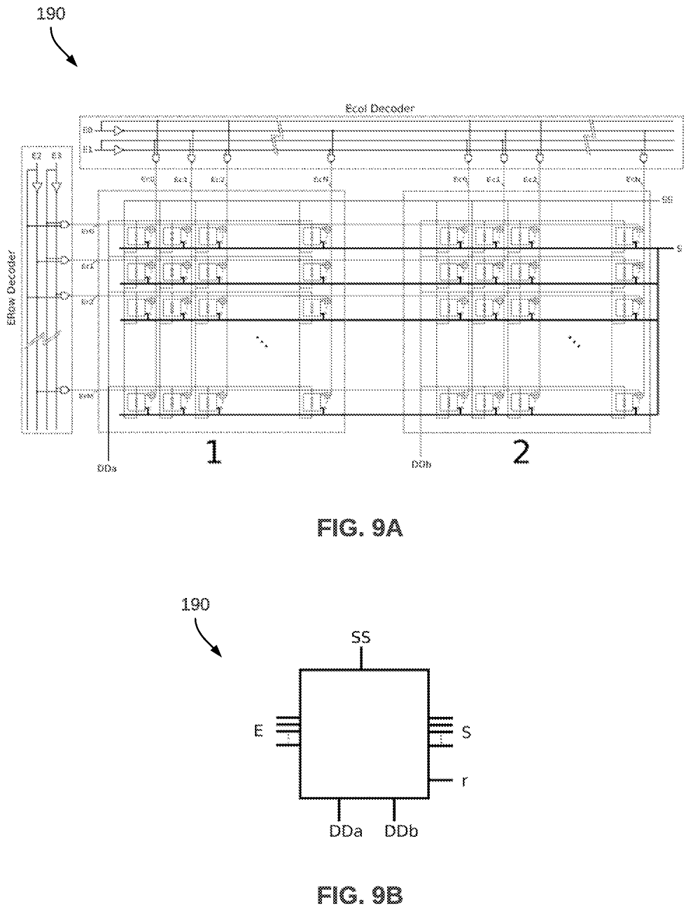

Differential representation is important in a number of contexts, and can easily be accomplished at the meta array level, as shown in the circuit diagram of meta array 190 in FIG. 9A and a symbolic representation of the meta array 190 in FIG. 9B. That is, FIG. 9A and 9B illustrates a schematic diagram of a differential-pair meta array, in accordance with an embodiment.

In the case of a differential-pair meta array, the column and/or row decoders can be shared such that the same relative unit crossbar is accessed in each of the two meta arrays. In this specific case we have joined the rows and duplicated the columns. We can further join in the inputs (SS) but keep the outputs separate (DDa, DDb). Combined with a memory-cell enable scheme (as in FIG. 7), such an architecture can provide a differential output on lines DDa and Ddb while allowing for arbitrary co-activation of differential pairs of unit crossbars.

It will be appreciated that variations of the above-disclosed and other features and functions, or alternatives thereof, may be desirably combined into many other different systems or applications. It will also be appreciated that various presently unforeseen or unanticipated alternatives, modifications, variations or improvements therein may be subsequently made by those skilled in the art which are also intended to be encompassed by the following claims.

What is claimed is:

1. A memristor apparatus, comprising:
at least one crossbar array and a memory bit M cell, the at least one crossbary array including unit crossbars;
a plurality of select bits that are shared; and
wherein an enable signal for each unit crossbar in the at least one crossbar array is generated by the memory bit M cell.

2. The memristor apparatus of claim 1, wherein the each unit crossbar shares select control lines and uses row/column enable lines.

3. The memristor apparatus of claim 1 wherein the at least one crossbar array comprises a meta array.

4. The memristor apparatus of claim 1 wherein the at least one crossbar array comprises a differential-pair meta array.

5. The memristor apparatus of claim 1 wherein the at least one crossbar array comprises a plurality of differential pairs of unit crossbars.

6. A meta array, comprising:
at least one crossbar array;
a memory bit M cell;
a plurality of select bits that are shared; and
wherein an enable signal for each unit crossbar in the at least one crossbar is generated by the memory bit M cell.

7. The meta array of claim 6, wherein the each unit crossbar shares select control lines and uses row/column enable lines.
